(19) United States
(12) Patent Application Publication
(10) Pub. No.: US 2017/0115355 A1
(43) Pub. Date: Apr. 27, 2017

(54) Maximum capacity estimator for battery state of health and state of charge determinations

(71) Applicant: Oxfordian, LLC, Dallas, TX (US)

(72) Inventors: Nicholas Dane Willard, Houston, TX (US); Michael G. Pecht, Hyattsville, MD (US)

(21) Appl. No.: 15/330,608

(22) Filed: Oct. 18, 2016

Related U.S. Application Data
(60) Provisional application No. 62/285,255, filed on Oct. 23, 2015.

(51) Int. Cl. G01R 31/36

(52) U.S. Cl. CPC G01R 31/361; G01R 31/3648; G01R 31/3682; G01R 31/3679

(57) ABSTRACT

A method for determining the maximum capacity a battery to store charge for the benefit of state of charge and state of health determinations, otherwise known as the maximum capacity estimator, is described. In an embodiment, a memory storage unit is used to collect input data from a battery or battery pack over the life cycle of the battery. As the battery operates, discharge cycles are analyzed to determine the similarity between different cycles throughout the operational phase. The maximum capacity at a given time for storing charge is then determined by comparing the trend of capacity loss in similar cycles and then applying that trend to the reduction of the maximum capacity of the battery. This method allows state of health and state of charge measurements to be made and updated with respect to battery degradation without the need for scheduled maintenance checks-ups such as mandatory discharge cycles or impedance/resistance measurements.

### FIELD OF INVENTION

The present invention relates to methods of determining battery capacity with the use of historical current and voltage data collected during battery operation. In particular, by the method and apparatus of this invention the maximum capacity for the purpose of real-time state of health (SOH) estimation and state of charge (SOC) recalibration is determined.

### BACKGROUND OF THE INVENTION

Lithium-ion (Li-ion) batteries have been applied as the portable power source in numerous systems including cellular phones, digital cameras, electric vehicles, and unmanned aerial vehicles. These batteries are appealing because they have high energy and power densities, long cycle lives, and perform well under a wide range of discharge profiles.

Unlike fossil fuel-powered systems, which store fuel and then convert it into energy through combustion, batteries are capable of storing energy regardless of the source, which could be a coal or nuclear power plant, wind turbine, or solar cell. This adds flexibility and allows for the utilization of environmental friendly technology. However, Li-ion battery reliability is often called into question due to the loss of performance that occurs with extended usage and/or storage. To quantify the loss of performance it is suitable to use maximum capacity or the battery's ability to store a given amount of electrical charge as a metric. As the battery degrades, the maximum amount of charge that it can hold is reduced; thus, the length of time that it can operate before it needs to be recharged becomes smaller.

Estimating a battery's maximum storage capacity at any given time during its operational life is a valuable asset to battery-operated systems. This information can be used to evaluate the degradation that has occurred in a battery over time. This indication of degradation is known as the battery's state of health (SOH). By relaying this information to a user, battery management systems can provide recommendations as to when critical maintenance or battery replacement should be performed. This allows corrective action to be taken before a battery becomes unable to perform its intended function within a specific application.

The ability to estimate a battery's maximum capacity is also important as a means to determine state of charge (SOC). The state of charge of a battery refers to the amount of electrical charge that is available for the user to extract from the battery. Physically, this can be related to the concentration of lithium that has migrated from the anode to the cathode during discharge. The voltage, or the potential difference of a battery is related to the amount of lithium that is contained within each electrode. As the battery discharges and the battery returns to its lower energy state, the voltage decreases non-linearly to a lower threshold. This lower voltage threshold in a lithium-ion battery is typically a non-zero value that is within the stability limits of the internal battery components. The voltage/lithium concentration relation can be utilized as a method for measuring the state of charge. To determine the voltage/lithium concentration relationship, a battery is usually discharged at a low current to minimize Ohmic and polarization effects, while the voltage is measured. The voltage curve collected during discharge can then be mapped to a zero to one scale which can be used to determine the state of charge.

State of charge allows a user to plan when the battery will need to be recharged. SOC is usually expressed as the percent remaining charge that is in a battery with respect to the amount of charge that the battery is able to hold in its fully charged state.

In order to determine the amount of charge that is remaining in a battery, often the Coulomb counting method has been used. This method uses a current sensor to measure the amount of current that enters or leaves a battery and then calculates the charge by integrating the current by time. Based on the amount of charge that has exited the battery, the residual charge remaining in the battery is calculated and compared with the maximum charge capacity to determine SOC. However, due to aging, the maximum charge capacity will degrade. If the maximum charge capacity used to calculate SOC does not change with the aging of the battery, then errors in the SOC estimation will arise.

Several techniques have been proposed to measure capacity for SOH estimation. Internal resistance measurements have been performed by applying a small current pulse to a battery while simultaneously measuring the observed voltage drop. Using Ohms Law, the internal resistance can be determined by dividing the difference between the initial and the final voltage by the initial and final current used to generate the current pulse. After determining the resistance, a relationship between maximum capacity and internal resistance can be established with a look-up table or by fitting the resistance data to a model that relates resistance to capacity or SOH.

One problem with this method is that in order to create a look-up table or a model that expresses the relationship between SOH and internal resistance, a large amount of training data and prior testing is required. Also, resistance measurements are typically noisy, so there is not much confidence in a single measurement. Instead, SOH must be determined over a large period of time and several measurements in order to establish the general trend in the internal resistance.

The AC impedance is sometimes used to measure maximum capacity and SOH in a Li-ion battery. This is performed by injecting an alternating current into a battery and then measuring its voltage response. This data is processed in order to determine the resistive and capacitive properties of the battery, which can then be fit to an equivalent circuit model. The problem with this method is that there are many different equivalent circuit models that could be used for a battery and determining which model to use can be difficult. Additionally, the hardware required for making AC impedance measurements can be bulky and over-sensitive, making its practicability in real-life applications difficult.

The most direct way of measuring the maximum capacity of a battery is the discharge method where a battery is discharged from its completely charged state to its completely discharged state and then the current is integrated by time and the maximum capacity can be found. The major problem with this method is that in real applications, users rarely completely discharge a battery. More often than not, a user will discharge a battery partially and then recharge the battery at their convenience.

### SUMMARY OF THE INVENTION

The present invention is made to solve the problems discussed above. The objective of the invention is to provide a system that is capable of determining the maximum amount of capacity that is available in a battery for the purpose of SOH estimation and SOC recalibration. As previously noted, as the battery degrades the maximum capacity decreases with increasing use, and thus the percent remaining capacity needs to be normalized to the new maximum capacity. Based on the embodiments of the invention, this can be achieved without the large amount of noise or extensive testing associated with internal resistance measurements, without the bulky or complex hardware required for AC impedance measurements, and without the requirement of a complete discharge to be performed in the case of the discharge test.

A current and voltage sensor is placed across a battery's terminals so that the charge entering and leaving a battery can be determined by integrating current by time. For each individual discharge cycle, the voltage sensor will record the voltage of the battery at the beginning and end of the discharge. The voltage at the end of discharge should be an estimate of the open circuit voltage which means that the measurement should be performed without any load on the battery. To reduce the effect of over potentials the start and end voltages should be measured several seconds after the last current load was placed on the battery. Typically the observed voltage asymptotically approaches the open circuit potential in a non-linear fashion after a current load is removed from the battery. By measuring the voltage multiple times during a small time interval with no load on the battery, the open circuit potential can be quickly estimated by extrapolating the voltage vs time curve. In this way, the optimal time for reading the end voltage can readily be determined for a given battery/battery pack.

The starting voltage, the ending voltage, and the charge released from the battery during every particular discharge cycle is logged into an onboard memory bank. As data is collected, the memory bank is organized such that all discharge cycles with similar starting and ending cut-off voltages will be grouped together. The loss of capacity found for discharges with similar starting and ending cut-off voltages will be used to calculate the amount of degradation that has occurred within the battery. Once the reduction of capacity is determined within each group of similar discharge cycles, the degradation trend of the maximum capacity can be found by projecting the amount of degradation that has occurred at partial discharge cycles on to the degradation of the maximum capacity. The degradation output by this method will be the reduction in maximum capacity.

### BRIEF DESCRIPTION OF THE DRAWINGS

The present invention is described with respect to particular exemplary embodiments thereof and reference is accordingly made to the drawings in which:

FIG. 1 provides a schematic representation of an embodiment of an apparatus necessary to carry out maximum capacity (i.e. state of charge) and state of health estimation.

FIG. 2 is a flowchart describing the process of maximum capacity estimation based on an embodiment of the disclosed invention.

FIG. 3 gives an organizational scheme in matrix from illustrating the grouping of similar discharges in order to determine the maximum capacity from partial discharge data, where ΔV₁₋₅ indicates the change in voltage from the start of discharge to the end of discharge and therefore giving a relative estimation of the amount a battery has been partially discharged.

FIG. 4 is a graph illustrating the reduction of maximum capacity as observed by complete charge/discharge cycles.

FIG. 5 is a graph illustrating the capacities observed during partial discharges and how the reduction of capacities for individual groups of similar cut off voltages can be reconstructed to determine the maximum capacity.

FIG. 6 is a graph showing the observed discharge capacity of a battery when obtained by randomly changing the cut-off voltages every 10 cycles.

FIG. 7 is a graph showing the observed discharge capacity of a battery when obtained by randomly changing the cut-off voltages every 10 cycles and the corresponding maximum capacity predicted by the current invention.

FIGS. 8A-E presents exemplary data of an illustrative example of degradation of a battery tested through 15 cycles, with FIG. 8A a table listing Vₘₐₓ−Vₘᵢₙ values for each of the reported cycles, and FIGS. 8B, 8C, 8D and 8E plots of the obtained data at 2 cycles, 5 cycles, 10 cycles and 15 cycles respectively.

### DETAILED DESCRIPTION OF THE INVENTION

A general example of the embodiments of the invention is described below with reference to the accompanying drawings. The invention is not limited to the construction set forth and may take on many forms embodied as both hardware and/or software. The invention may be embodied as an apparatus, a system, a method, or a computer program. The numbers are used to refer to elements in the drawings. In many cases these elements are shown to be coupled, which may refer to a direct physical connection between the elements in which data or power or information may be shared, or it may refer to a software computing process which requires information from one sequence to be fed into a following sequence. It is also understood that in any such coupling, there may be other elements in between such connections that may include, but are not limited to, power scaling or signal modulation devices.

As stated above, the health of a battery-operated system is often quantified by the amount of charge that it is capable of storing. While a battery is in operation or in storage, physical degradation mechanisms reduce the amount of charge the battery can store in its fully charged state. In the paper K. Ng, C-S Moo, Y-P Chen, Y-C Hsieh, “Enhanced Coulomb counting method for estimating state-of-charge and state-of-health of lithium-ion batteries,” Applied Energy, 86 (2009), pp. 1506-1511, state of health is defined as:

$$SOH = \frac{{Q}_{MAX}}{{Q}_{rated}} 100 \%$$

where Q_{MAX} is the maximum capacity of the battery measured during any point in the battery's life, and Qrated is the rated capacity or the nominal capacity, which represents the maximum amount of charge the battery could hold at the beginning of life. (Mathematically, the maximum capacity can be described by the formula Qₘₐₓ=∫_{V}_{ₘᵢₙ}^{V}^{ₘₐₓ} Idt). Therefore, SOH can be thought of as the percentage of maximum available storage capacity compared to the maximum amount of capacity at the beginning of life, and it can be used to suggest when the battery needs to be replaced. The same paper defines state of charge as:

$$SOC = \frac{{Q}_{MAX} - {Q}_{released}}{{Q}_{MAX}} 100 \%$$

where Q_{released} is the amount of charge that can be released from the battery at any point during its discharge process. Thus SOC can be thought of as the percentage of charge remaining in a battery, and it describes when a battery needs to be recharged.

In both of these definitions, the value of maximum capacity is required for the state of health estimation to be made. Traditionally, in battery monitoring it is the value of the maximum capacity at any given point in time that is most difficult to determine. This problem arises because in expressing the state of charge, it is required to know how much charge is available in the battery; however, to directly determine the amount of charge that is available in a battery, the battery must be completely discharged and the amount of electrical charge measured upon the completion of the discharge. Therefore, the maximum charge of the battery cannot be known until after the discharge has been completed.

Additionally, a problem is apparent when a battery is not completely discharged and, therefore, the maximum amount of charge in the battery cannot be measured though integration of current by time. This has resulted in research efforts to estimate the maximum amount of charge either by assuming the capacity of the last recorded complete discharge, or by using resistance-based techniques to relate maximum capacity to internal cell resistance or impedance. An embodiment of the present invention, as is more fully described below, allows the maximum capacity, Q_{MAX}, to be estimated without the use of impedance measurements and without waiting for a complete discharge cycle to occur.

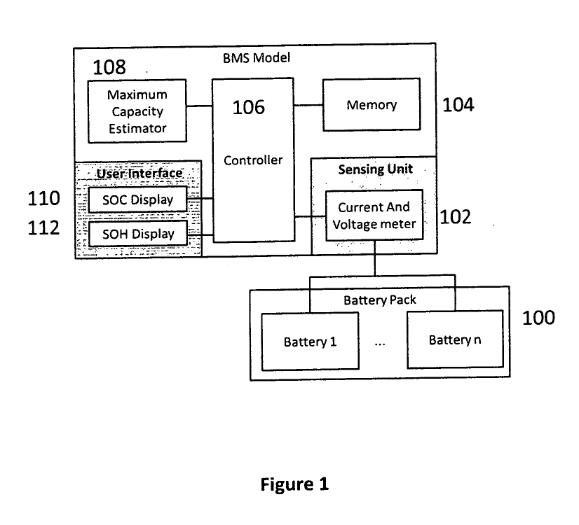

FIG. 1 illustrates an embodiment for a general apparatus required for the present invention to be realized. The subject of monitoring could be a single cell battery or battery pack as represented by (100) with n number of individual cells. A connection between the terminals of each cell and a battery monitoring system (BMS) would be required in order to monitor the current and voltage of each cell in the pack. It in an embodiment of the invention, one can also monitor the overall current and voltage of the battery pack. However, one would still need to monitor the individual cells in order to be able to specifically pin point where within the battery pack the degradation was occurring, or where it was most advanced.

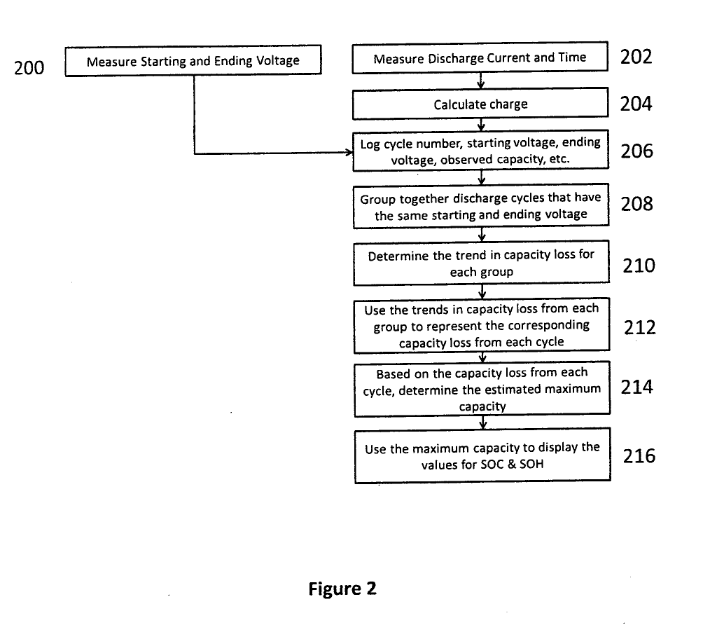

The current and voltage of each cell would be measured by a current and voltage sensor (102), which could be one of any numerous kinds of current and voltage sensors that are available, but would likely be embodied as an integrated circuit. These sensors would be part of a sensing subsystem on the BMS and could also include other sensors, such as temperature sensors, which could be used to collect information on the physical characteristics of each battery cycle. The current and voltage sensors are connected to a controller (106) whose over-all function is to govern the timing and interactions between components of the BMS system. The controller is used to designate the sampling rate of the current and voltage sensor; it initiates the data storage sequence in the memory component (104); it calls on stored data in the memory component to run the maximum capacity estimator (108) whose inner workings will become apparent in connection with the discussion of FIG. 2-FIG. 6; and it relays the output of the maximum capacity estimator to a user interface (110, 112), which displays the value of SOC and SOH for the user's convenience. The specific workings of the individual components described in FIG. 1 are all generally well known except for the maximum capacity estimator (108), which comprises the core of the invention.

FIG. 2 outlines the general process by which the maximum capacity estimator operates. On the first level (200, 202) the discharge current and voltage sensors measure individual cells of a battery pack or the end terminals of a multi-cell battery pack. Discharge current and voltage is distinguished between charge current and voltage by the direction of the current, which in a current sensor is indicated by the sign, either positive or negative, of the current. The sign of the current corresponding to current leaving the battery are denoted as the discharge current, and voltage measurements that correspond with the discharge current are denoted as discharge voltage measurements.

For rechargeable batteries, usage consists of charging currents, discharging currents, and periods of rest (where the current is effectively zero). Any span of time in which a battery is in consecutive states of discharge or rest without experiencing a charging current is considered a single discharge cycle. Therefore, when the current being measured by the current sensor senses a change from a charging current to a discharging current (or a current of 0), the beginning of a discharge cycle is denoted and the voltage corresponding to this time is defined as the starting voltage, or Vₛₜₐᵣₜ^{c}, where the superscript c indicates the cycle number of the battery. When the current being measured by the current sensor changes from a discharging current (or a current of 0) to a charging current, the end of a discharge cycle will be denoted and the voltage corresponding to this time will be defined as the end voltage, or V_{end}^{c}. The charge that is released by the battery between Vₛₜₐᵣₜ^{c} and V_{end}^{c} will be calculated by integrating the discharge current over the discharge time and then summated over the entire discharge cycle. This cumulated value of charge will be known as the observed capacity, or Q_{observed}^{c} (204). At the end of every discharge cycle, the values of Vₛₜₐᵣₜ^{c}, V_{end}^{c}, Q_{observed}^{c}, and the cycle number c will be stored (206) in the on-board memory device. The formula is Q_{observed}=∫_{V}_{_{end}}^{V}^{ₛₜₐᵣₜ} Idt

In an embodiment, when measuring Vₛₜₐᵣₜ and V_{end}, considerations must be made for the drop in measured voltage due to internal resistance. This voltage drop is known as the ohmic drop and is proportional to the applied current during charge or discharge according to Ohm's law. The voltage drop could be a confounding factor when measuring Q_{equivalent} especially for applications in which varying discharge currents are used during operation. In order to prevent the applied current from affecting the values of Vₛₜₐᵣₜ and V_{end}, it is preferred that the voltage values be measured after current is removed from the battery and the battery has returned to steady state. The voltage under no load is often referred to as the open circuit potential and can be directly related to the state of charge of the battery. By using the open circuit potential as the reference point for Vₛₜₐᵣₜ and V_{end}, the relationship between voltage measurements will be constant regardless of the discharge current that has been applied during usage.

As the battery undergoes usage and collects data from multiple discharge cycles the maximum capacity estimator will group together discharge cycles which have occurred under similar conditions (208). In order to group similar discharge conditions together, the technician or designer may define some criteria which would allow two discharge cycles to be considered similar. The similarity distinction may be determined by a number of criteria. Machine learning algorithms used for data clustering such as k-nearest neighbor, or density-based spatial clustering may be used to identify values of Vₛₜₐᵣₜ^{x}−V_{end}^{x} that are similar to each other between different cycles. Another possible criterion that may be used to define when two discharge cycles are similar is if for two different cycles c=x and c=x+n, the values of Vₛₜₐᵣₜ^{x}−V_{end}^{x}, and the values of Vₛₜₐᵣₜ^{x+n}−V_{end}^{x+n} are within 0.1V of one another. However, the value of this criteria and the actual criteria itself may be different based on the specific needs and sensitivities of the particular system.

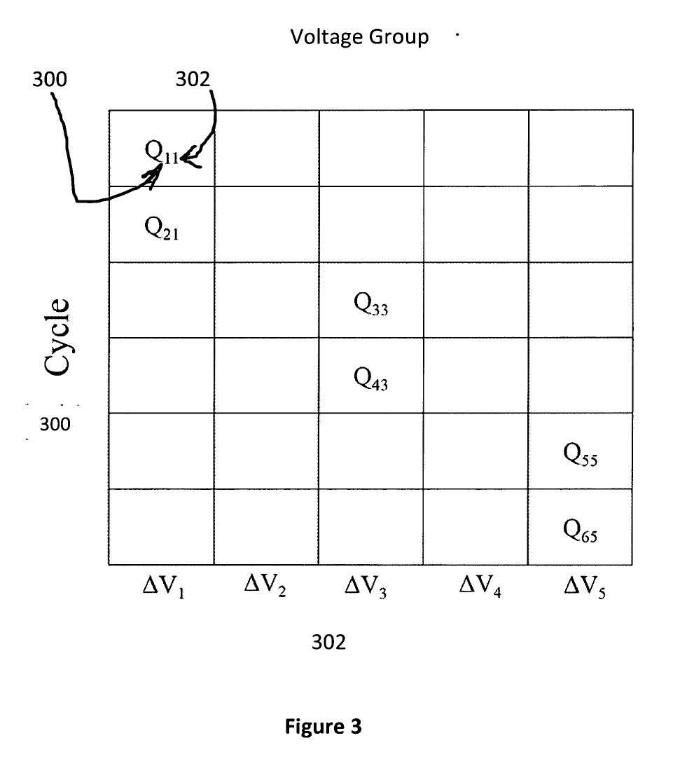

Given an appropriate amount of usage time, numerous discharge cycles will be collected. These cycles will be grouped according to their similarity. This data must be organized in such a way that the observed capacities, the cycle numbers, and the designated similarity groups can all be called upon in a systematic way. One way in which this can be performed is to express the data in matrix form as indicated in FIG. 3. This matrix (provided for illustrative purposes only) Qᵢⱼ gives the observed capacity at each cycle where the subscript i (300) denotes the cycle number and j (302) denotes the similarity group. Note that the ΔV assigned to each grouping of data can be set in the setting up of the Maximum Capacity Estimator.

With the discharge data organized in this structure the trend in capacity degradation for each individual similarity group (210) can be determined. Generally degradation occurs more slowly for shorter partial discharge cycles. By organizing the data in this manner, the degradation rate for different length partial discharges can be individually determined. In the case of the matrix a trend can be determined for the data in each individual column j. The method by which data trending is performed can include in an embodiment of the invention, but is not limited to, linear and nonlinear regression, neural network, and gradient boosted regression.

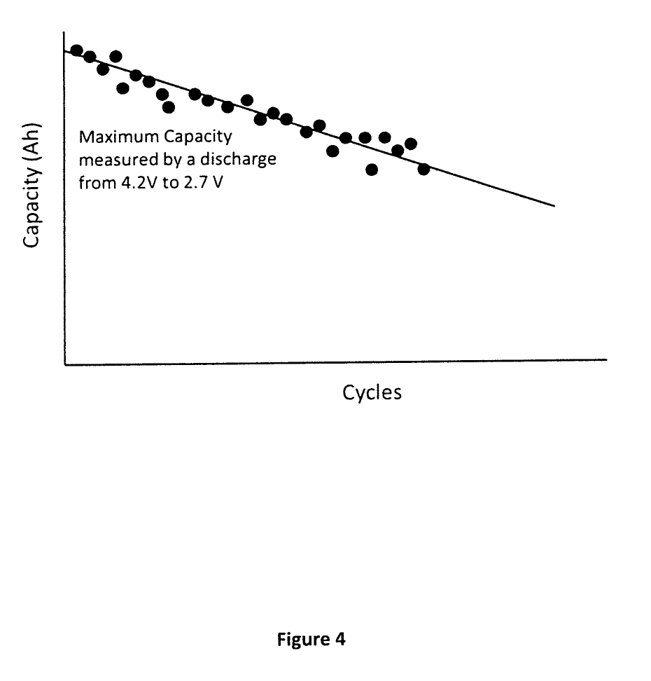

The motivation for organizing data into similarity groups and performing trending analysis on each similarity group separately is illustrated in FIG. 4. This figure shows a typical capacity fade curve for a commercially available battery having a manufacturer recommended Vₘᵢₙ=2.7 and Vₘₐₓ 4.2, as presented in much of the body of technical battery literature; see for example S-W Eom et al “Life Prediction and Reliability Assessment of Lithium Secondary Batteries,” Journal of Power Sources, 174 (2007), pp 954-958. The general consensus in the technical battery community is that battery degradation, and hence state of health, is indicated by the reduction of a battery's maximum capacity. Maximum capacity can be shown explicitly by performing a cycle life test where the battery is fully charged and fully discharged and the capacity is calculated through the integration of current by time. Then the value of the capacity is plotted for each cycle. In FIG. 4 it is apparent that the reduction of the observed capacity is due to the internal degradation of the battery because all other parameters of charging and discharging, such as the external temperature, Vₛₜₐᵣₜ^{c} and V_{end}^{c}, are kept constant. (If the temperature of a particular application is not kept constant then a thermal model can be incorporated into the BMS that accounts for the temperature vs maximum capacity relationship. Generally the maximum capacity decreases with decreasing temperature and this can be accounted for with an Arrhenius relationship.)

Because the parameters governing the discharge of the battery are kept constant, it can confidently be assumed that the reduction of capacity is due to physical degradation phenomena which reduces the amount of charge the battery is able store. The problem with observing degradation in this manner, as mentioned above, is that complete discharge cycles do not always occur. Rather the user more often decides to charge the battery mid-way through the discharging process as is convenient for that particular user. Or the user, may from time to time turn off the phone within a complete discharge cycle in order to conserve charge. In this instance of several on/off events, they are considered as a single discharge cycle. In the first scenario, the full amount of charge available in the battery cannot be measured. In such case, the observed capacity (the capacity measured during that particular discharge) will be lower than would have been observed in a complete discharge, but this reduction in capacity is due to the discharge cycle being cut short rather than any physical degradation in the battery.

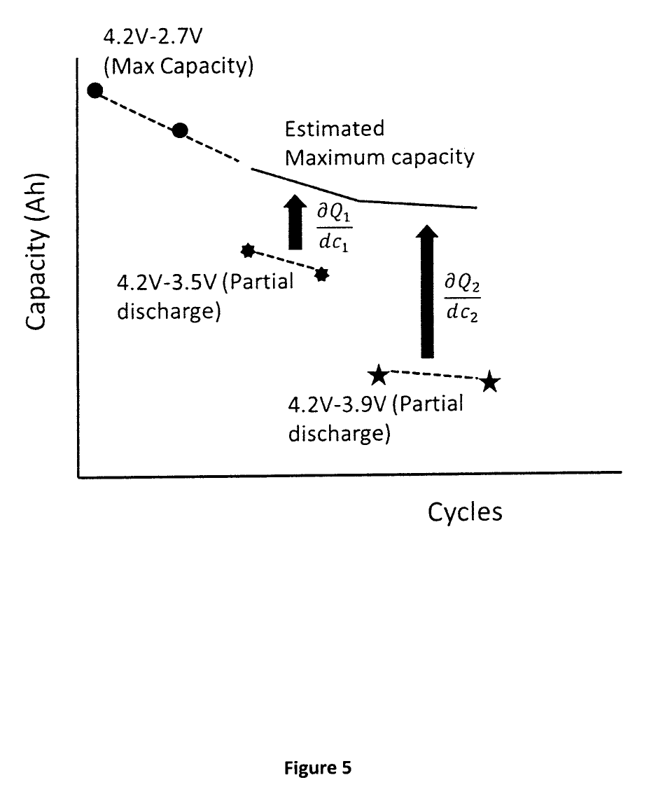

FIG. 5 shows a schematic of 6 different observed discharge capacities. In this diagram it is assumed that all the Vₛₜₐᵣₜ values are the same. The capacities of the first two discharge cycles are shown as circles. In these cycles the battery underwent a full discharge, where the end of charge occurred when the voltage sensor over the battery's terminals read 2.7V. The reduction of capacity between the first and second cycle was due to capacity fade (degradation) of the battery. The slope of the degradation between the first two capacity measurements is shown by a dotted line and can be calculated by any of the trending analysis methods mentioned above. The third and fourth cycles are shown as seven-point stars. These points represent the capacity of the same battery when the discharge cycle was cut off at 3.5V. It can be clearly seen that there is a large drop between the first and second cycles and the third and fourth cycles; however, this drop in capacity can be due to two factors. First, it can be due to the reduction of capacity of the battery by degradation but secondly it is due to the discharge cycles being cut off early (at 3.5V rather than 2.7V). Therefore, not all the charge that the battery was capable of holding was able to be measured. This same procedure is repeated for the 3rd group of cycles indicated by the 5 point stars. These cycles had a similar cut-off voltage and were therefore grouped in the 3.9V cut-off voltage group. The decrease in capacity between these cycles was determined and the rate of capacity decrease between these cycles was assumed to be the same rate of capacity decreased for Qₘₐₓ.

In order to differentiate between the capacity drop that was caused by degradation and the capacity drop that was caused by different cycle parameters, according to an embodiment of this invention battery degradation is determined by comparing only similar discharge cycles or ones that have effectively the same cycling parameters (212). Comparing similar cycles cancels out the effects on the observed capacity that are caused by differences in cycling parameters. By determining the trend in capacity reduction between cycles three and four, the trend in capacity loss due to degradation can be determined. With this information the maximum capacity can be determined by taking the previous maximum capacity determined during cycle two, and assuming that over cycles three and four, the maximum capacity had reduced by the same amount indicated by the reduction of the third and fourth partial cycles (214).

This same logic can then be applied to cycles five and six, which is shown as a five point star and gives the capacities of the battery when the discharge was cut off at a voltage of 3.9. Again in cycles five and six the capacity dropped suddenly due to the differences in cut-off voltage. A dotted line is shown between cycles five and six to indicate the trend in the capacity loss due to degradation during these cycles. Using this slope the reduction of maximum capacity between cycles four and five and between five and six are assumed to be the same trend found in the observed capacity values of cycles five and six.

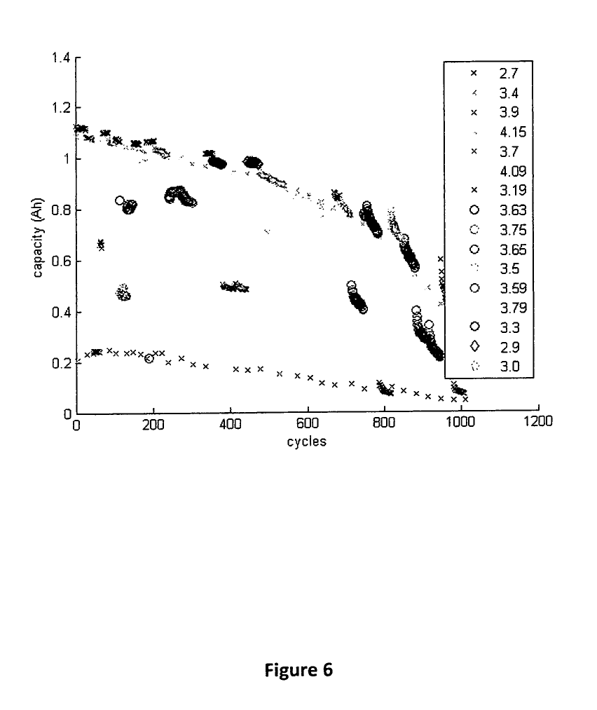

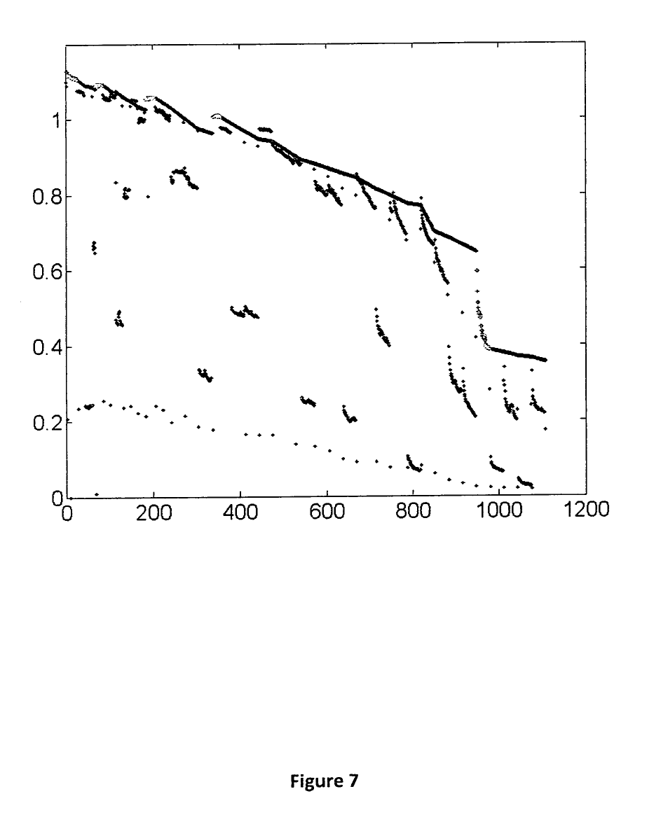

According to an embodiment of the invention, similar discharge cycles are used to determine the trend in capacity fade and then that same trend is applied to the assumed maximum capacity in order to best estimate the true value of maximum capacity while taking into consideration the degradation effects. In the previous description, schematic diagrams were used to illustrate the underlying process. FIG. 6 and FIG. 7 taken together demonstrate the effectiveness of maximum capacity estimator using real battery test data. FIG. 6 plots the discharge capacities of a lithium-ion cell phone battery with a maximum rated capacity of 1.1 Ah (where Ah=amp hours) that was cycled to failure. Every 10 cycles the value of V_{end} was randomly changed to simulate a battery undergoing partial discharge cycles of varying lengths (as would be experienced in many real-life applications). The key to the right side of the graph shows all the cut-off voltages that were used, and the points on the graph show the resulting observed capacities and their respective cycle numbers.

The application of the current invention was demonstrated on this same battery, and the results are shown in FIG. 7. This shows the observed capacities as the light grey points while the resulting estimated maximum capacity is shown in by the dark grey points. Using the resulting estimated maximum capacity, the SOC and SOH were determined by the equations stated previously (216).

The generalized mathematic notation which describes the overall operating principle of the maximum capacity estimator can be described as:

$${Q}_{MAX}^{c} = {Q}_{MAX}^{c - 1} ( 1 + \frac{d {Q}_{similar}}{d {c}_{similar}} )$$

where the estimated maximum capacity at some cycle c can be determined by using the previous estimated maximum capacity Q_{MAX}^{c-1} and adding to it the associated change in that maximum capacity. This change in maximum capacity is determined by the change in capacity between two discharge cycles that are considered similar dQₛᵢₘᵢₗₐᵣ over the change in their respective cycle numbers dcₛᵢₘᵢₗₐᵣ.

As Qmax cannot always be expected to be directly measured due to unpredictable user discharge profiles, in field applications, current and time data are used to calculate Q_{observed}, which is the capacity calculated during any particular discharge cycle. This value will be subjected to large fluctuations depending on the depth of discharge (DOD) of any particular discharge and therefore will not be equal to Qmax. To calculate Qc during any particular discharge we use:

Q_{observed}=∫_{V}_{_{end}}^{V}^{ₛₜₐᵣₜ} Idt

where I is current in Amperes, t is the time in hours between each particular sample.

At the end of each discharge cycle, i.e. when the current supplied by the battery switches form a negative value to a positive value, the open current voltage recorded is V_{end}. If V_{end} is equal to the manufacturer recommended discharge cut-off voltage and Vcharge is the manufacturer recommended charge cut-off voltage then Q_{observed}=Qₘₐₓ^{c}. If not, then Q_{observed} must be converted into a form that can be compared to Qmax.

During controlled battery cycling tests, charge and discharge profiles are normally all conducted with the same cut-off voltage. Thus, when a decrease in capacity is observed, it can be attributed to degradation phenomena occurring within the battery. If battery cycling is conducted where each particular discharge cycle is cut-off at a random voltage, then changes in capacity would be mostly attributed to DOD and the contribution from battery degradation would be lost in the noise. Because SOH is concerned with battery degradation and not DOD it makes sense to only calculate SOH based on the rate of capacity fade between capacity values that were determined between the same cut-off voltages. In literature V_{end} is most often selected as the manufacturer's recommended cut off voltage so that SOH can be calculated in terms of Q_{rated}. However if one adheres to the assumption that changes in capacity measured at the same cutoff voltage are indicative of battery degradation (rather than DOD), then the rate of charge of any two capacities evaluated at the same cut-off voltage, can be used to identify the rate of change in the battery's SOH. Because we still want to evaluate SOH in terms of Qrated we can introduce a term Q equivalent which assumes the value of Qmax but degrades at a rate indicated by two comparable Q_{observed} values.

In order to correctly interpret this data, each updated Qmax value should be normalized with respect to Qrated so that the data is shown in the SOH range. Also, due to the way this data was processed, these SOH values exist in the cycle domain. Because each cycle interval is considered equivalent, time information is lost. In order to overcome this and make meaningful remaining useful life predictions, each cycle should be interpreted as an average user cycle where the time of each cycle is calculated by:

$$\overline{t} = \frac{{{Σ}_{k = 1}^{c} ( {Σ}_{i = 1}^{n} {t}_{i} )}_{k}}{c}$$

where i is a sample and k is a cycle number. Using this value, future predictions in the cycle domain can easily be converted to the time domain by simply calculating t̅ at the time of prediction. The value however must be recalculated before every prediction because it will change based on the users typical usage behavior.

### ILLUSTRATIVE EXAMPLE

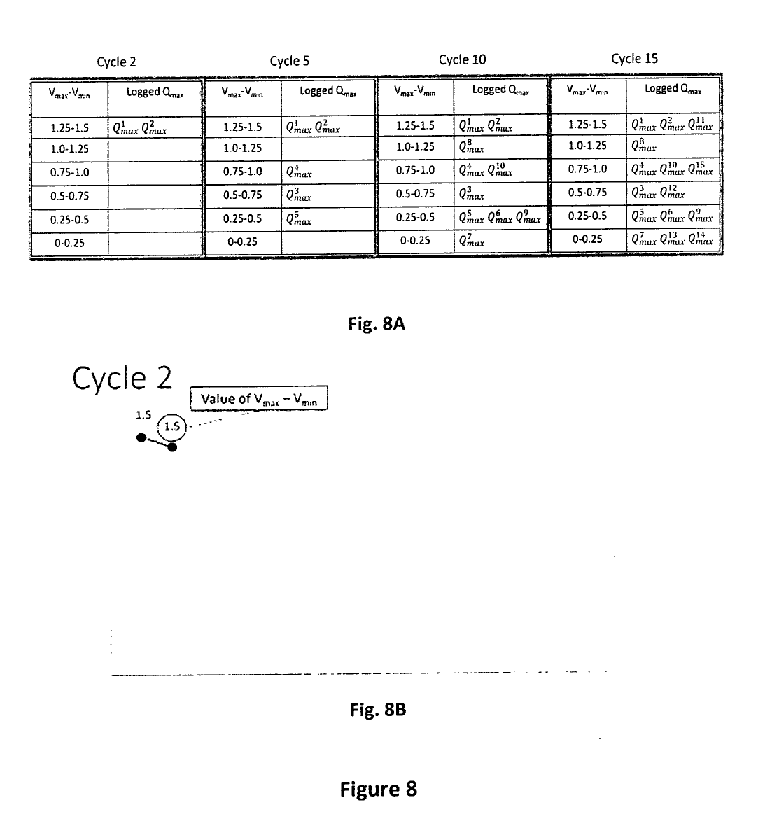

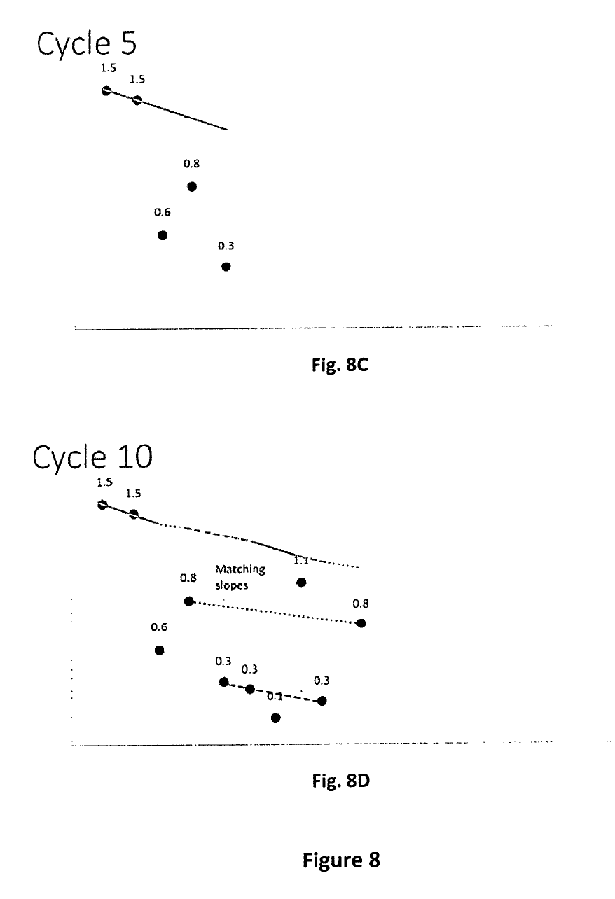

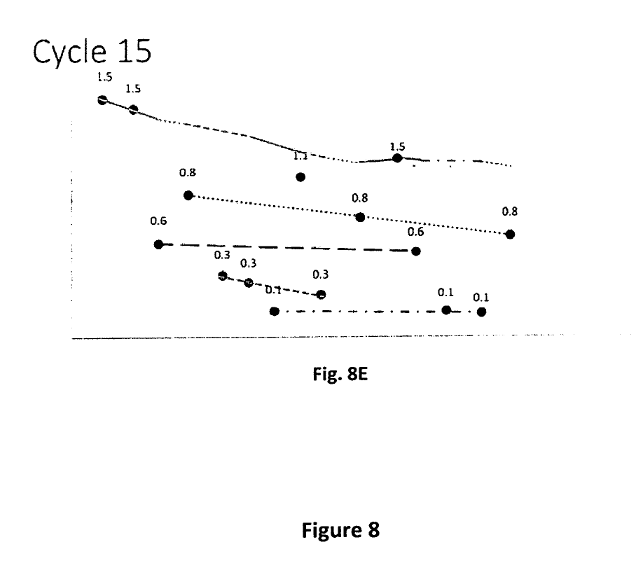

A working example for the estimation of the maximum capacity is shown with reference to FIG. 8. In this example, a battery undergoes 15 charge/discharge cycles in which only 3 of the cycles are considered to be full discharges. The voltage at the beginning of the discharge cycle and the voltage observed at the end of the discharge cycle are collected and the difference between these two cycles are calculated as Vₘₐₓ−Vₘᵢₙ. The capacities observed over the first 15 cycles are binned according to their Vₘₐₓ−Vₘᵢₙ value. The data is reported in the table (FIG. 8A), and drawn out in illustrative plots FIGS. 8B, 8C, 8D and 8E.

In the first 2 cycles (FIG. 8B), both discharges underwent complete discharge cycles and therefore the measured capacity can be considered to be the maximum capacity. After the 5^{th} cycle (FIG. 8C) there are no partial discharge cycles that were discharged with the same Vₛₜₐᵣₜ−V_{end}. Therefore the assumed degradation of the maximum capacity follows the previously observed degradation slope.

After the 10^{th} cycle (FIG. 8D), there are 2 values of Vₛₜₐᵣₜ−V_{end} that have matching partial discharge cycles. The slopes of these partial discharges are calculated with linear regression. The assumed degradation rate of the maximum capacity over the course of these partial discharge cycles are equal to the degradation rate of the observed discharge capacity cycles with similar Vₛₜₐᵣₜ−V_{end} values.

Finally, after the 15^{th} cycle, there are 4 values of Vₛₜₐᵣₜ−V_{end} that have matching partial discharge cycles. The 11^{th} cycle underwent a full discharge and is therefore considered the maximum capacity regardless of the previous slope.

The foregoing detailed description of the present invention is provided for purposes of illustration and is not intended to be exhaustive or to limit the invention to the embodiments disclosed, the scope of the invention limited only the clams hereto.

What we claim is:

1. A method for estimating the maximum capacity of a battery comprising:
providing current and voltage sensors connected across a battery which is connected to a load;
measuring the voltage and current of said battery at the start of a load cycle,
measuring the voltage and current of said battery at the end of said load cycle, said measurements taken sometime after the load has been disconnected from said battery, and there is no longer a load on the battery.
determining the observed discharge capacity of said battery at the end of said cycle and assigning an attribute to the discharge cycle;
comparing attributes of the current discharge cycle with other discharge cycles that have been stored in a memory unit;
determining which discharge cycles in the memory unit are similar to the current discharge cycle based on attributes;
using the recorded cycle numbers and capacities of the similar discharge cycles in order to determine the trend in capacity change with cycle number; and thereafter,
using the trend in capacity change of similar discharge cycles to project the capacity change of the maximum capacity.

2. The method of claim 1 where discharge capacity is determined by the integration of current by time at the end of a single discharge cycle according to the formula Q_{released}=∫_{V}_{_{end}}^{V}^{ₛₜₐᵣₜ} Idt.

3. The method of claim 1 where the end of a discharge cycle is denoted when the current measured by the current sensor indicates a change from the discharging state to the charging state.

4. The method of claim 3 where the beginning of a discharge cycle is denoted when the current measured by the current sensor indicates a change from the charging state to the discharging or rest state.

5. The method of claim 1 where supplementary data to characterize specific attributes of the cycle is comprised of the open circuit voltage corresponding to the beginning of a discharge cycle, the open circuit voltage corresponding to the end of a discharge cycle.

6. The method of claim 1 where comparing specific attributes of the discharge cycles in order to determine if the cycles are similar can be performed with a similarity criterion.

7. The method of claim 6 where a similarity criterion denotes a specific range of voltage values Vₘₐₓ−Vₘᵢₙ between which the attributes of individual cycles must be contained in order to be considered similar.

8. The method of claim 1 in which clustering techniques may be used to denote similarity between individual cycles' start and end voltages.

9. The method of claim 1 where the trend in capacity change with respect to cycle number is performed for the current cycle in question and all discharge cycles stored in the memory unit which were determined to be similar to the current cycle.

10. The method of claim 1 where the determination of the maximum capacity is made by projecting the change in capacity observed between similar cycles onto the maximum capacity.

11. The method of claim 15 where the initial maximum capacity is defined by the rated capacity of the battery.

12. The method of claim 10 where the reduction of the initial maximum capacity is determined when the first two similar cycles are observed.

13. The method of claim 11 where the trend in the reduction of maximum capacity is considered equivalent to the trend in the reduction of the capacity of similar cycles.

14. The method of claim 12 where a mathematical expression for the updating of the maximum capacity is represented by the formula:
$${Q}_{MAX}^{c} = {Q}_{MAX}^{c - 1} ( 1 + \frac{d {Q}_{similar}}{d {c}_{similar}} )$$

15. The method of claim 13 where the determination of the maximum capacity Q_{MAX}^{c} is re-evaluated every time a discharge cycle has been determined to be similar to a previous discharge cycle logged in the memory unit.

16. The method of claim 3 where the maximum capacity can be re-evaluated every time the open-circuit voltage measured at both the beginning and end of discharge corresponds to the maximum and minimum voltage of the battery respectively.

17. The method of claim 14 where the SOC is determined using the obtained value of Q_{MAX} and then calculating SOC according to the formula:
$$SOC = \frac{{Q}_{MAX} - {Q}_{released}}{{Q}_{MAX}} 100 \%$$
Where Q_{released} is determined by the formula Q_{released}=∫_{V}_{ₘᵢₙ}^{V}^{ₘₐₓ} Idt.

18. The method of claim 1 where the SOH is determined using the value of Q_{MAX} obtained by the formula
$${Q}_{MAX}^{c} = {Q}_{MAX}^{c - 1} ( 1 + \frac{d {Q}_{similar}}{d {c}_{similar}} ) ,$$
and then calculating SOH by using the formula:
$$SOH = \frac{{Q}_{MAX}}{{Q}_{rated}} 100 \%$$

19. The method of claim 18 where Q_{released} is determined by the integration of current by time beginning at the time corresponding to the beginning of discharge as until the time in which the user is requesting to know the value of SOC.

20. An apparatus for estimating a battery's maximum capacity for state of charge and state of health estimation comprising: a maximum capacity estimator; a display unit which outputs values of SOC and SOH using an estimated value of maximum capacity; a memory unit housing historical data collected though the battery's operational life; a sensing system for measuring both the current and voltage across a battery; and a controller providing communication and control between all related subsystems.
